(19) United States
(12) Patent Application Publication
(10) Pub. No.: US 2025/0128630 A1
(43) Pub. Date: Apr. 24, 2025

(54) CHARGING A BATTERY TO A CORRECTED STATE OF CHARGE

(71) Applicant: Ford Global Technologies, LLC, Dearborn, MI (US)

(72) Inventors: Patterson Abraham, Dearborn, MI (US); Ai Keramidas, West Bloomfield, MI (US)

(21) Appl. No.: 18/491,710

(22) Filed: Oct. 20, 2023

(51) Int. Cl. B60L 53/62; B60L 58/12

(52) U.S. Cl. CPC B60L 53/62; B60L 58/12; B60L 2240/545; B60L 2240/547; B60L 2240/549

(57) ABSTRACT

Systems and methods for estimating a state of charge of a traction battery are described. In one example, a state of charge estimate may be corrected via one of three different state of charge estimates. The one of three different state of charge estimates may be selected based on state of charge correction values or traction battery operating conditions.

### TECHNICAL FIELD

The present description relates to a method and system for charging a traction battery of an electric vehicle.

### BACKGROUND AND SUMMARY

An electric vehicle may include a traction battery that supplies electric charge to a propulsion source to propel the electric vehicle. The traction battery has an electric charge storage capacity that may be displayed to or communicated to a human or autonomous driver so that it may be known when it may be desirable to recharge the traction battery. The electric charge storage capacity may be presented to the driver as a state of charge (SOC) value that may range from 0-100%. The SOC may not be directly measured, but it may be inferred. One way to infer SOC may be to monitor flow of electric current into and out of the traction battery, which be referred to as Coulomb counting. However, the SOC as determined from Coulomb counting may not be as accurate as may be desired due to signal to noise ratios at lower current flow rates. Errors in the SOC estimate may not allow the electric vehicle to travel as far as may be expected due to the battery holding less charge than is reported, or alternatively, the vehicle owner/operator may be assessed more than may be expected to charge the battery to a requested SOC due to over estimating the amount of charge that is stored in the battery. As such, it may be desirable to provide a way to determine battery SOC in a way that may be less sensitive to electrical noise at lower current flow rates.

The inventors herein have recognized the above-mentioned issues and have developed a method for charging a traction battery of a vehicle to a requested SOC, comprising: retrieving from memory a predetermined number of SOC correction values accumulated during charging of the traction battery via a first SOC estimation algorithm, a second SOC estimation algorithm, or a third SOC estimation algorithm; charging the traction battery; correcting a present SOC estimate via a selected SOC estimation algorithm to generate a corrected SOC, the selected SOC estimation algorithm selected from a plurality of algorithms; and ceasing charging of the traction battery based on the corrected SOC.

By ceasing charging of a traction battery in response to a corrected SOC that is based on a selected SOC estimation algorithm that is selected from a plurality of algorithms, it may be possible to generate a more accurate SOC estimate during vehicle operating conditions when Coulomb counting to estimate SOC may be less accurate. The plurality of algorithms may include an algorithm that is based on battery open circuit voltage (OCV) and an algorithm that is based on instantaneous battery operating conditions.

The present description may provide several advantages. In particular, the approach may enhance battery SOC estimation during conditions where Coulomb counting may be less accurate. Further, the approach may compensate SOC estimates for vehicle and battery operating conditions. Additionally, the approach may control battery charging so that a traction battery may be charged to a level that is closer to a requested SOC level.

The above advantages and other advantages, and features of the present description will be readily apparent from the following Detailed Description when taken alone or in connection with the accompanying drawings.

The summary above is provided to introduce in simplified form a selection of concepts that are further described in the detailed description. It is not meant to identify key or essential features of the claimed subject matter, the scope of which is defined uniquely by the claims that follow the detailed description. Furthermore, the claimed subject matter is not limited to implementations that solve any disadvantages noted above or in any part of this disclosure.

### BRIEF DESCRIPTION OF THE DRAWINGS

The advantages described herein will be more fully understood by reading an example of an embodiment, referred to herein as the Detailed Description, when taken alone or with reference to the drawings, where:

FIG. 1 is a schematic diagram of a vehicle that includes an electric energy storage device and an electric machine for propulsion;

FIG. 2 shows a plot of a relationship between open circuit voltage of a battery and battery state of charge;

FIG. 3 is a flowchart of a first method for estimating battery state of charge;

FIG. 4 is a flowchart of a second method for estimating battery state of charge;

FIG. 5 is a flowchart of a third method for estimating battery state of charge;

FIG. 6 is a flowchart of a first way for selecting a battery state of charge estimation algorithm to determine battery state of charge; and

FIG. 7 is a flowchart of a way to select a SOC estimation algorithm and correct a battery state of charge estimate based on a plurality of battery state of charge corrections.

### DETAILED DESCRIPTION

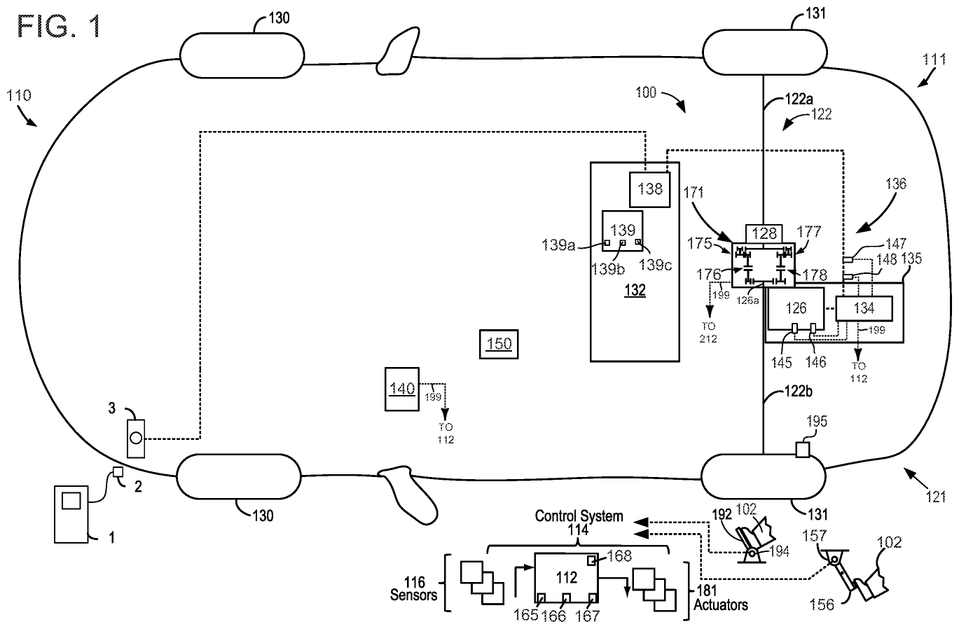

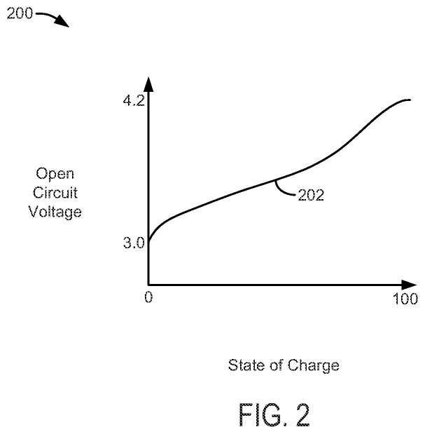

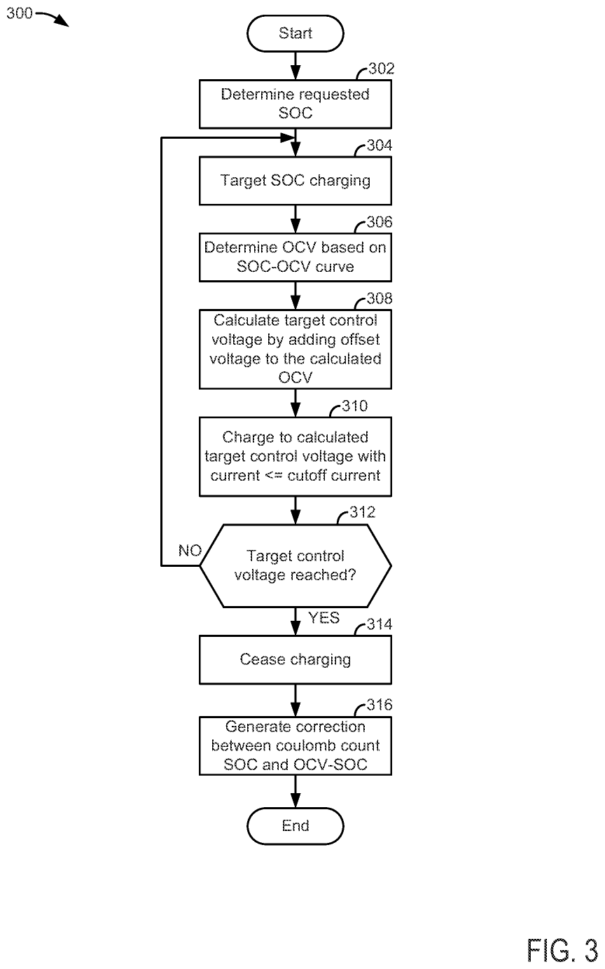

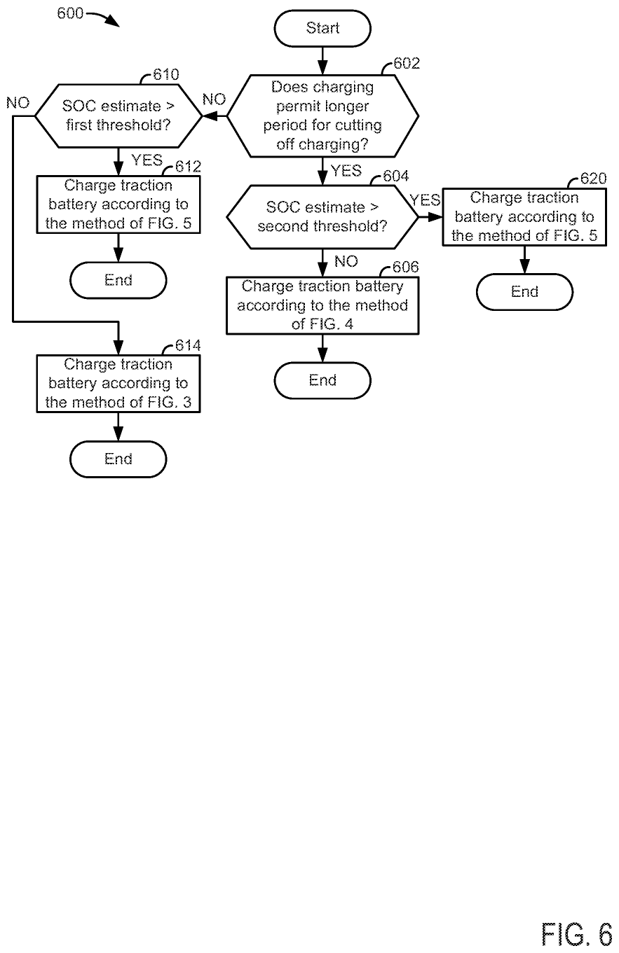

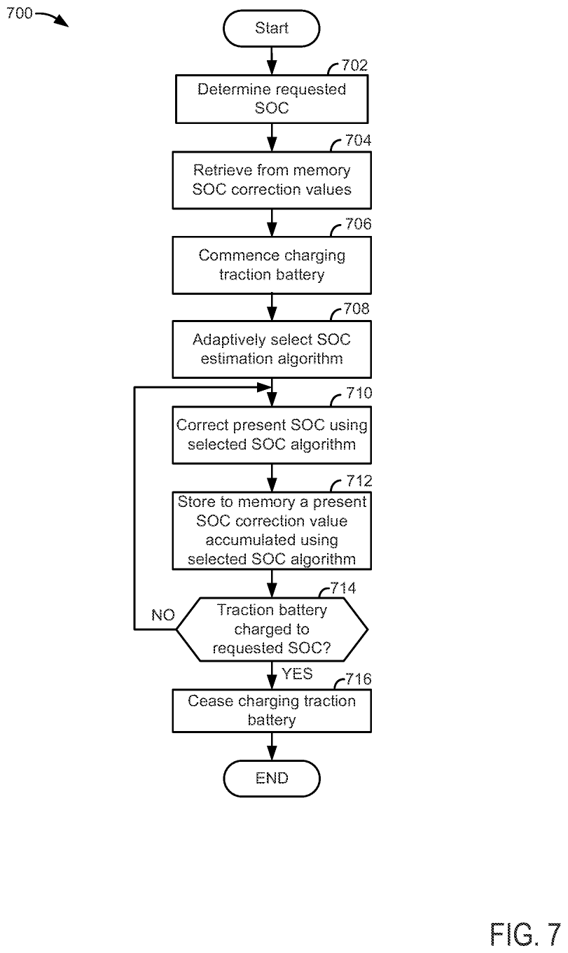

The present description is related to charging a traction battery of an electric vehicle. In particular, three different methods for estimating traction battery SOC and charging the traction battery according to estimated SOC are disclosed. The electric vehicle may be of the type shown in FIG. 1. A relationship between an open circuit voltage (OCV) of a battery and battery SOC is shown in FIG. 2. FIGS. 3-5 show flowcharts of methods for estimating and correcting traction battery SOC. FIGS. 6 and 7 show flowcharts of ways to select a SOC correction method from a plurality of SOC correction methods.

FIG. 1 is a schematic diagram of a vehicle 121 including a powertrain or vehicle propulsion system 100. A front portion of vehicle 121 is indicated at 110 and a rear portion of vehicle 121 is indicated at 111. Vehicle propulsion system 100 includes electric machine 126. Electric machine 126 may consume or generate electrical power depending on its operating mode. Throughout FIG. 1, mechanical connections between various components are illustrated as solid lines, whereas electrical connections between various components are illustrated as dashed lines.

Vehicle propulsion system 100 has a rear axle 122. In some examples, rear axle 122 may comprise two half shafts, for example first half shaft 122a, and second half shaft 122b. Vehicle propulsion system 100 further has front wheels 130 and rear wheels 131. Rear wheels 131 may be driven via electric machine 126.

The rear axle 122 is coupled to electric machine 126. Rear drive unit 136 may transfer power from electric machine 126 to axle 122 resulting in rotation of rear wheels 131. Rear drive unit 136 may include a gearbox 171 including a low gear 175 and a high gear 177 that are coupled to electric machine 126 via output shaft 126a of electric machine 126. Low gear 175 may be engaged via fully closing low gear clutch 176. High gear 177 may be engaged via fully closing high gear clutch 178. High gear clutch 178 and low gear clutch 176 may be opened and closed via commands received by rear drive unit 136 over controller area network (CAN) 199. Alternatively, high gear clutch 178 and low gear clutch 176 may be opened and closed via digital outputs or pulse widths provided via control system 114. Rear drive unit 136 may include differential 128 so that torque may be provided to first half shaft 122a and to second half shaft 122b. In some examples, an electrically controlled differential clutch (not shown) may be included in rear drive unit 136.

Electric machine 126 may receive electrical power from onboard electrical energy storage device 132. Furthermore, electric machine 126 may provide a generator function to convert the vehicle's kinetic energy into electrical energy, where the electrical energy may be stored at electric energy storage device 132 for later use by electric machine 126. An inverter system controller (ISC) 134 may convert alternating current generated by electric machine 126 to direct current for storage at the electric energy storage device 132 and vice versa. Electric drive system 135 includes electric machine 126 and inverter system controller 134. Inverter system controller may include a microcontroller, memory (e.g., random-access memory and read-only memory), and input/output circuitry (not shown). Electric energy storage device 132 may be a battery (e.g., a traction battery that provides energy to propel a vehicle), capacitor, inductor, or other electric energy storage device. Electric power flowing into electric drive system 135 may be monitored via current sensor 145 and voltage sensor 146. Position and speed of electric machine 126 may be monitored via position sensor 147. Torque generated by electric machine 126 may be monitored via torque sensor 148.

In some examples, electric energy storage device 132 may be configured to store electrical energy that may be supplied to other electrical loads residing on-board the vehicle (other than the motor), including cabin heating and air conditioning, engine starting, headlights, cabin audio and video systems, etc.

Control system 114 may communicate with electric machine 126, energy storage device 132, inverter system controller 134, etc. Control system 114 may receive sensory feedback information from electric drive system 135 and energy storage device 132, etc. Further, control system 114 may send control signals to electric drive system 135 and energy storage device 132, etc., responsive to this sensory feedback. Control system 114 may receive an indication of an operator requested output of the vehicle propulsion system from a human operator 102, or an autonomous controller. For example, control system 114 may receive sensory feedback from driver demand pedal position sensor 194 which communicates with driver demand pedal 192. Pedal 192 may refer schematically to a driver demand pedal. Similarly, control system 114 may receive an indication of an operator requested vehicle braking via a human operator 102, or an autonomous controller. For example, control system 114 may receive sensory feedback from brake pedal position sensor 157 which communicates with brake pedal 156.

Energy storage device 132 may periodically receive electrical energy from a power source such as fast charging station 1 of a stationary power grid (not shown) residing external to the vehicle (e.g., not part of the vehicle). As a non-limiting example, vehicle propulsion system 100 may be configured as a plug-in electric vehicle (EV), whereby electrical energy may be supplied to electric energy storage device 132 via the fast charging station 1 and the power grid (not shown). The fast charging station may be electrically coupled to a vehicle receptacle 3 via a plug 2. The receptacle 3 may be electrically coupled to the electric energy storage device 132.

Electric energy storage device 132 includes an electric energy storage device controller 139 and a power distribution module 138. Electric energy storage device controller 139 may provide charge balancing between energy storage element (e.g., battery cells) and communication with other vehicle controllers (e.g., controller 112). Further, controller 139 may control charging of electric energy storage device 132. Electric energy storage device controller 139 includes a core or processor 139a, memory 139b (e.g., read-only and/or random-access), and analog and digital inputs/outputs 139c. Power distribution module 138 controls flow of power into and out of electric energy storage device 132.

One or more wheel speed sensors (WSS) 195 may be coupled to one or more wheels of vehicle propulsion system 100. The wheel speed sensors may detect rotational speed of each wheel. Such an example of a WSS may include a permanent magnet type of sensor.

Controller 112 may comprise a portion of a control system 114. In some examples, controller 112 may be a single controller of the vehicle. Control system 114 is shown receiving information from a plurality of sensors 116 (various examples of which are described herein) and sending control signals to a plurality of actuators 181 (various examples of which are described herein). As one example, sensors 116 may include tire pressure sensor(s) (not shown), wheel speed sensor(s) 195, etc. In some examples, sensors associated with electric machine 126, wheel speed sensor 195, etc., may communicate information to controller 112, regarding various states of electric machine operation. Controller 112 includes non-transitory (e.g., read-only memory) 165, random access memory 166, digital inputs/outputs 168, and a microcontroller 167. Controller 112 may receive input data and provide data to human/machine interface 140 via CAN 199. Controller 112 may be a controller that is additional to inverter system controller 134, or alternatively, it may be a controller that is part of inverter system controller 134. Controller 112 may receive vehicle navigation and travel route data (e.g., travel distance, start of travel location, end of travel location, direct current fast charge (DCFC) station locations, road grades, geographical data, etc.) from navigation system 150.

Thus, the system of FIG. 1 provides for a system, comprising: a traction battery; and a controller including executable instructions that cause the controller to correct a Coulomb based battery state of charge value in response to a battery voltage, a battery current, and a battery temperature based battery state of charge estimate. In a first example, the system further comprises additional executable instructions that cause the controller to look up a correction value for the traction battery based on the battery voltage, the battery current, and the temperature based battery state of charge estimate. In a second example that may include the first example, the system further comprises additional executable instructions to supply charge to the traction battery for a predetermined amount of time. In a third example that may include one or both of the first and second examples, the system further comprises additional executable instructions to supply charge to the traction battery via less than a threshold amount of current. In a fourth example that may include one or more of the first through third examples, the system further comprises additional executable instructions to report when the battery state of charge is equal to a requested battery state of charge. In a fifth example that may include one or more of the first though fourth examples, the system includes where the requested battery state of charge is received via a human/machine interface. In a sixth example that may include one or more of the first through fifth examples, the system further comprises additional executable instructions to reset an amount of time that the traction battery has been charging to zero.

In another representation, the system of FIG. 1 provides for a system, comprising: a traction battery; and a controller including executable instructions that cause the controller to receive a requested state of charge (SOC) for the traction battery, retrieve from memory a predetermined number of SOC correction values accumulated during charging of the traction battery via a first SOC estimation algorithm, a second SOC estimation algorithm, or a third SOC estimation algorithm, charge the traction battery to the requested SOC, and correct a present SOC estimate via a selected SOC estimation algorithm to achieve the requested SOC. In a first example, the system further comprises additional executable instructions that cause the controller to charge the battery to voltage corresponding to the SOC with current less than a cutoff current. In a second example, the system further comprises additional executable instructions to correct SOC based on an amount of time charging the traction battery since the traction battery was most recently coupled to electric vehicle supply equipment. In a third example that may include one or both of the first and second examples, the system includes where the first SOC algorithm is based on a battery open circuit voltage. In a fourth example that may include one or more of the first through third examples, the system includes where the second SOC algorithm is based on an instantaneous SOC estimate. In a fifth example that may include one or more of the first through fourth examples, the system includes where the instantaneous SOC estimate is based on an instantaneous voltage of the traction battery and an instantaneous current of the traction battery. In a sixth example that may include one or more of the first through fifth examples, the system includes where the third SOC algorithm is based on a battery open circuit voltage while the traction battery is maintained with zero input and output current.

Referring now to FIG. 2, a plot 200 that shows a relationship between an open circuit battery voltage and a traction battery state of charge (SOC) is shown. The vertical axis represents the open circuit battery voltage and the open circuit voltage increases in the direction of the vertical axis arrow. The open circuit voltage may be measured via a volt meter when no electrical load is coupled to the battery. The horizontal axis represents traction battery SOC and SOC increases from the left side of FIG. 2 to the right side of FIG. 2. Curve 202 shows the relationship between battery open circuit voltage and battery state of charge.

In one example, curve 202 may be stored in controller memory and referenced by open circuit voltage of a traction battery. The referenced curve outputs a battery open circuit voltage when a requested traction battery SOC is used to reference the curve or function that represents curve 202.

Referring now to FIG. 3, a first method for charging a traction battery to a requested state of charge is shown. Method 300 may be performed via a controller (e.g., electric energy storage device controller 139) in cooperation with the system of FIG. 1 to control traction battery charging. At least portions of method 300 may be included in and cooperate with a system as shown in FIG. 1 as executable instructions stored in non-transitory memory. The method of FIG. 3 may cause the controller to actuate the actuators in the real world and receive data and signals from sensors described herein when the method is realized as executable instructions stored in controller memory.

At 302, method 300 determines a requested SOC. In one example, a human vehicle operator may request a SOC value to a value greater than zero and less than or equal to 100%. The human vehicle operator may input the requested SOC into a human/machine interface 140. Alternatively, a cloud server may request that the vehicle be charged to a particular SOC value via a satellite, cellular network, or means of communication. The requested SOC may also be referred to as the SOC that is based on OCV (e.g., SOCocv). The requested SOC may be converted into a requested SOC for each battery cell of the traction battery. Thus, the requested SOC may be for an individual or sole battery cell of a traction battery. Method 300 proceeds to 304.

At 304, method 300 begins charging the traction battery so that traction battery may be charged to the requested SOC. The charging may commence via sending a signal or data to electric vehicle supply equipment (EVSE) (not shown). The EVSE may supply charge to the traction battery at a predetermined rate or at a rate that has been requested via the vehicle controller. Method 300 proceeds to 306.

At 306, method 300 determines an open circuit voltage corresponding to the requested battery SOC. The target or requested SOC that was determined at 304 may be used to reference a table or function (e.g., as shown in FIG. 2) and the table or function outputs a target or requested traction battery OCV from the requested or target battery SOC. Method 300 proceeds to 308 after the target or requested battery OCV is determined.

At 308, method 300 determines a target control voltage for the traction battery by adding an offset voltage to the target open circuit voltage for the battery that was determined at 306. For example, if the target battery open circuit voltage is 3.6 volts, an offset voltage of 40 millivolts volts may be added to the target open circuit battery voltage of 3.6 volts to generate a 3.64 volt target control voltage for the battery of the traction battery. The offset voltage may be incrementally increased at a predetermined rate until the target voltage is reached. Method 300 proceeds to 310.

At 310, method 300 charges the traction battery to the calculated target or requested control voltage determined at 308. The battery of the traction battery may be charged to the target or requested voltage for the battery with an electric current amount until the electric current falls below a threshold current (e.g., a cutoff current). Method 300 may periodically cease charging of the individual traction battery for a short amount of time to measure the OCV of the traction battery. Method 300 proceeds to 312.

At 312, method 300 judges whether or not the traction battery OCV is equal to greater than the target control voltage. If so, the answer is yes and method 300 proceeds to 314. Otherwise, the answer is no and method 300 returns to 304. Method 300 may determine the OCV for the traction battery at predetermined time intervals by decoupling the traction battery from external loads and measuring the traction battery voltage.

At 314, method 300 ceases charging the traction battery since the traction battery open circuit voltage is equal to or greater than the open circuit voltage that is associated with the requested SOC. Method 300 proceeds to 316.

At 316, method 300 generates a correction value between a Coulomb counting method for determining SOC and estimating SOC according to the open circuit voltage (OCV) method for estimating SOC. The correction is stored with other corrections determined in the same way during other traction battery charging sessions in controller random access memory. In one example, the correction may be determined via the following equation:

$$SOCcor 1 = ( SOCcoul - SOCocv ) \cdot {G}_{1}$$

where SOCcor1 is a SOC correction value based on counted coulombs and open circuit voltage, SOCcoul is SOC estimated from Coulomb counting

$$( e . g , SOCcoul ( t ) = SOCcoul ( {t}_{0} ) + {\int }_{{t}_{0}}^{t} \frac{I}{{Q}_{n}} .$$

dt, where t is time, t₀ is an initial time, I is current, and Qₙ is charge capacity of the battery), SOCocv is the SOC that is based on the OCV for the individual battery cell of the traction battery, and G₁ is a predetermined gain value (e.g., a real number). Method 300 proceeds to exit.

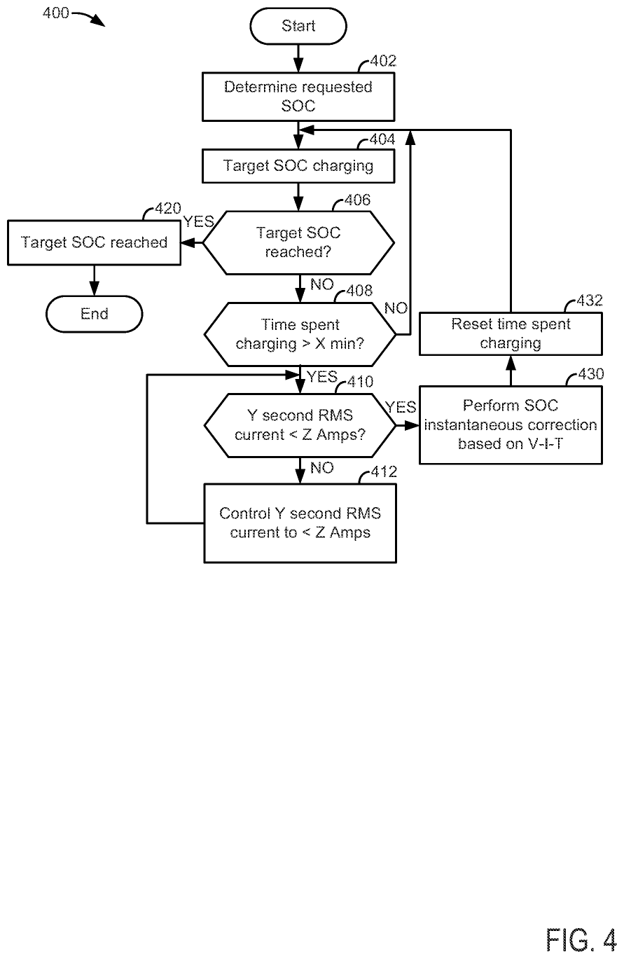

Referring now to FIG. 4, a second method for charging a traction battery to a requested state of charge is shown. Method 400 may be performed via a controller (e.g., electric energy storage device controller 139) in cooperation with the system of FIG. 1 to control traction battery charging. At least portions of method 400 may be included in and cooperate with a system as shown in FIG. 1 as executable instructions stored in non-transitory memory. The method of FIG. 4 may cause the controller to actuate the actuators in the real world and receive data and signals from sensors described herein when the method is realized as executable instructions stored in controller memory.

At 402, method 400 determines a requested SOC. In one example, a human vehicle operator may request a SOC value to a value greater than zero and less than or equal to 100%. The human vehicle operator may input the requested SOC into a human/machine interface 140. Alternatively, a cloud server may request that the vehicle be charged to a particular SOC value via a satellite, cellular network, or means of communication. Method 400 proceeds to 404.

At 404, method 400 performs target SOC charging. Target SOC charging comprises adjusting a SOC charge level of a traction battery to a level that is requested according to a vehicle occupant or cloud server target or requested SOC for the entire traction battery. In other words, the SOC value that is input by vehicle occupants or the cloud server is converted to a requested or target SOC value for a battery of the traction battery and charge is supplied to the battery and battery so that the target SOC level for the battery may be reached. A correction value may be added to the requested or target SOC value to determine a corrected SOC and charge may be supplied so that the SOC of the battery reaches the corrected SOC value. The initial correction value may be zero. Method 400 proceeds to 406.

At 406, method 400 judges whether or not the target or requested SOC for the battery has been reached. In one example, method 400 determines whether or not the target SOC for the battery has been reached by determining whether or not a Coulomb counting based SOC for the battery plus an SOC correction for the battery is greater than or equal to (e.g., >=) the target or requested SOC for the battery. If so, the answer is yes and method 400 proceeds to 420. Otherwise, the answer is no and method 400 proceeds to 408.

At 420, method 400 reports that the target or requested SOC for the individual battery cell has been reached via a message on a human/machine interface. Method 400 ceases charging the battery and exits.

At 408, method 400 judges whether or not an amount of time charging the traction battery beginning from the time that the vehicle was most recently electrically coupled to EVSE and began receiving charge, or alternatively, the time since the charging timer was most recently reset, is greater than a first threshold amount of time (e.g., X minutes where “X” is a variable). If so, the answer is yes and method 400 proceeds to 410. Otherwise, the answer is no and method 400 returns to 404. Method 400 makes the assessment of charging time so that a meaningful correction voltage may be determined and so that corrections may be less sensitive to signal noise if present.

At 410, method 400 judges whether or not Y second root mean square (RMS) current (e.g. RMS current measured over Y seconds) entering or exiting the traction battery is less than Z amps, where Y is a predetermined time interval and Z is a predetermined amount of electric current. If method 400 judges that Y second RMS electric current is less than Z, then the answer is yes and method 400 proceeds to 430. Otherwise, the answer is no and method 400 proceeds to 412. In this way, method 400 may determine whether or not current flow through the battery is sufficiently low that an accurate instantaneous SOC estimate may be determined even though the battery voltage being measured is not an open circuit voltage.

At 412, method 400 controls the Y second RMS current flow to the battery to less than Z amps. In one example, method 400 may command the EVSE to adjust electric current supplied to the traction battery so that current flow through the battery may be less than Z amps. Method 400 returns to 410.

At 430, method 400 performs instantaneous SOC correction based on voltage, current, and battery temperature (V-I-T). In one example, method 400 may reference a table that holds empirically determined SOC estimates. The table may be reference via instantaneous battery voltage (e.g., battery voltage with current flowing from or to the battery), instantaneous battery current, and battery temperature. In one example, a SOC correction may be determined via the following equation:

$$SOCcor 2 = ( SOCcoul - SOCinst ) \cdot {G}_{2}$$

where SOCcor2 is a correction value based on counted coulombs and instantaneous SOC, SOCcoul is SOC estimated from Coulomb counting

$$( e . g , SOCcoul ( t ) = SOCcoul ( {t}_{0} ) + {\int }_{{t}_{0}}^{t} \frac{I}{{Q}_{n}} .$$

dt, where t is time, t₀ is an initial time, I is current, and Qₙ is charge capacity of the battery), SOCinst is the SOC that is based on the instantaneous SOC as determined from instantaneous battery voltage, instantaneous battery current, and instantaneous battery temperature referencing a table or function of empirically determined SOC values. G₂ is a predetermined gain value (e.g., a real number). The instantaneous battery voltage may be determined from the battery when a load is connected to the battery and current is flowing through the battery. Thus, the instantaneous voltage is not an open circuit voltage. In other examples, method 400 may determine an offset correction value (e.g., 20 millivolts) that is added to SOCcoul(t) to generate a corrected SOC. Method 300 proceeds to 432.

The correction is stored with other corrections determined in the same way during other traction battery charging sessions in controller random access memory. Method 400 proceeds to 432.

At 432, method 400 resets the charging timer (e.g., a timer that tracks an amount of time since the most recent reset of the charging timer or an amount of time since the vehicle was most coupled to the EVSE and began receiving charge) so as to reset the amount of time that the battery has been receiving charge to zero. Method 400 returns to 404.

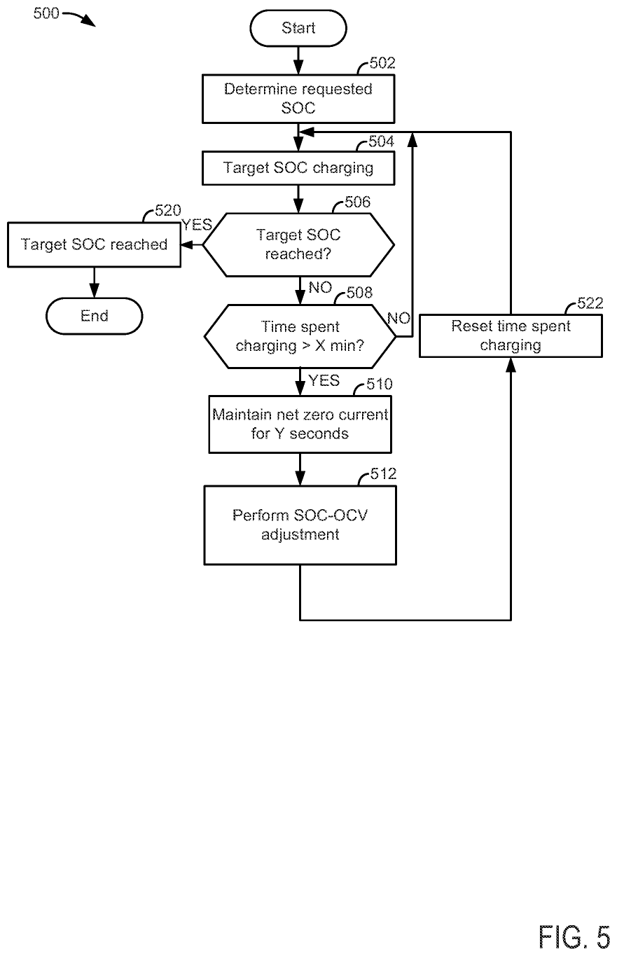

Referring now to FIG. 5, a third method for charging a traction battery to a requested state of charge is shown. Method 500 may be performed via a controller (e.g., electric energy storage device controller 139) in cooperation with the system of FIG. 1 to control traction battery charging. At least portions of method 500 may be included in and cooperate with a system as shown in FIG. 1 as executable instructions stored in non-transitory memory. The method of FIG. 5 may cause the controller to actuate the actuators in the real world and receive data and signals from sensors described herein when the method is realized as executable instructions stored in controller memory.

At 502, method 500 determines a requested SOC. In one example, a human vehicle operator may request a SOC value to a value greater than zero and less than or equal to 100%. The human vehicle operator may input the requested SOC into a human/machine interface 140. Alternatively, a cloud server may request that the vehicle be charged to a particular SOC value via a satellite, cellular network, or means of communication. The requested SOC may be converted into a requested SOC for each battery cell of the traction battery. Thus, the requested SOC may be for an individual or sole battery cell of a traction battery. Method 500 proceeds to 504.

At 504, method 500 performs target SOC charging. Target SOC charging comprises adjusting a SOC charge level of an traction battery to a level that is requested according to a vehicle occupant or cloud server target or requested SOC for the entire traction battery. In other words, the SOC level that is input by vehicle occupants or the cloud server is converted to a requested or target SOC level for an battery of the traction battery and charge is supplied to the battery and battery so that the target SOC level for the battery may be reached. A correction value may be added to the requested or target SOC value to determine a corrected SOC and charge may be supplied so that the SOC of the battery reaches the corrected SOC value. The initial correction value may be zero. Method 500 proceeds to 506.

At 506, method 500 judges whether or not the target SOC has been reached. In one example, method 500 determines whether or not the target SOC for the battery has been reached by determining whether or not a Coulomb counting based SOC for the battery plus an SOC correction for the battery is greater than or equal to (e.g., >=) the target or requested SOC for the battery. If so, the answer is yes and method 500 proceeds to 520. Otherwise, the answer is no and method 500 proceeds to 508.

At 520, method 500 reports that the target or requested SOC for the battery has been reached via a message on a human/machine interface. Method 500 ceases charging the battery and exits.

At 508, method 500 judges whether or not an amount of time charging the traction battery beginning from the time that the vehicle was most recently electrically coupled to EVSE and began receiving charge, or alternatively, the time since the charging timer was most recently reset, is greater than a first threshold amount of time (e.g., X minutes where “X” is a variable). If so, the answer is yes and method 500 proceeds to 510. Otherwise, the answer is no and method 500 returns to 504. Method 500 makes the assessment of charging time so that a meaningful correction voltage may be determined and so that corrections may be less sensitive to signal nose if present.

At 510, method 500 maintains zero electric current flow into and out of the traction battery for a predetermined amount of time (e.g., Y seconds). By temporarily suspending charging of the traction battery, a better estimate of SOC may be obtained so that the traction battery may be charged closer to the requested SOC. Method 500 proceeds to 512.

At 512, method 500 performs a SOC-OCV adjustment or correction. In one example, the correction may be determined via the following equation:

$$SOCcor 3 = ( SOCcoul - SOCocv ) \cdot {G}_{3}$$

where SOCcor3 is a correction value based on counted coulombs and open circuit voltage, SOCcoul is SOC estimated from Coulomb counting

$$( e . g , SOCcoul ( t ) = SOCcoul ( {t}_{0} ) + {\int }_{{t}_{0}}^{t} \frac{I}{{Q}_{n}} .$$

dt, where t is time, t₀ is an initial time, I is current, and Qₙ is charge capacity of the battery), SOCocv is the SOC that is based on the OCV, and G₃ is a predetermined gain value (e.g., a real number). The correction is stored with other corrections determined in the same way during other traction battery charging sessions in controller random access memory. In other examples, method 500 may determine an offset correction value (e.g., 20 millivolts) that is added to SOCcoul(t) to generate a corrected SOC. Method 500 proceeds to 522.

At 522, method 500 resets the charging timer (e.g., a timer that tracks an amount of time since the most recent reset of the charging timer or an amount of time since the vehicle was most coupled to the EVSE and began receiving charge) so as to reset the amount of time that the battery has been receiving charge to zero. Method 500 returns to 504.

Thus, method 500 charges the traction battery for a predetermined amount of time, maintains current flow into and out of the traction battery at zero after the predetermined amount of time, and estimates SOC from the battery OCV after maintaining the traction battery current at zero amperes. This may allow the SOC to be accurately determined during charging whether the current flow into the battery is larger or smaller during the charging process. Accordingly, it may be possible to provide accurate SOC estimates whether the traction battery is charged via a supercharger or a home charging station. Turning now to FIG. 6, a method for selecting a traction battery charging procedure from a plurality of traction battery charging procedures is shown. Method 600 may be performed via a controller (e.g., electric energy storage device controller 139) in cooperation with the system of FIG. 1 to control traction battery charging. At least portions of method 600 may be included in and cooperate with a system as shown in FIG. 1 as executable instructions stored in non-transitory memory. The method of FIG. 6 may cause the controller to actuate the actuators in the real world and receive data and signals from sensors described herein when the method is realized as executable instructions stored in controller memory.

At 602, method 600 judges whether or not the EVSE and the vehicle owner/user permit a longer period of time where charge can be cutoff during a time when the vehicle is electrically coupled to the EVSE. In one example, the longer period of time may be a period of time that may range from 2 minutes to 10 minutes. The user may input an amount of time that charge may be cutoff to and from the battery so that a more reliable relationship between OCV and SOC may be achieved to estimate the SOC. Further, some EVSE may or may not accommodate periods of cutting off current supplied to the battery based on EVSE utilization in the vehicle's immediate area, ambient air temperature, and other parameters. If method 600 determines that electric current may be cut off from the traction battery for longer periods of time while the vehicle is electrically coupled to the EVSE, the answer is yes and method 600 proceeds to 604. Otherwise, the answer is no and method 600 proceeds to 610.

At 604, method 600 judges whether or not the SOC estimate is or is expected to be greater than a second threshold SOC. In one example, method 600 may judge that the SOC is or is expected to be greater than the second threshold SOC based on the initial battery SOC immediately before charging, the rate of charge to be delivered to the traction battery, and an expected amount of time to charge the traction battery. If method 600 judges that the SOC estimate during charging will or is expected to exceed a second threshold amount of charge, the answer is yes and method 600 proceeds to 620. Otherwise, the answer is no and method 600 proceeds to 606.

At 620, method 600 selects the method of FIG. 5 and charges the vehicle's traction battery according to the method of FIG. 5. The method of FIG. 5 may provide more accurate SOC estimates when cutting off charge to the traction battery is permitted while the vehicle is electrically coupled to the EVSE and when SOC estimates are or are expected to be greater than a second threshold SOC amount. Method 600 proceeds to exit.

At 606, method 600 selects the method of FIG. 4 and charges the vehicle's individual traction battery according to the method of FIG. 4. The method of FIG. 4 may provide more accurate SOC estimates when cutting off charge to the traction battery is permitted while the vehicle is electrically coupled to the EVSE and when SOC estimates are or are expected to be less than a second threshold SOC amount. Method 600 proceeds to exit.

At 610, method 600 judges whether or not the SOC estimate is or is expected to be greater than a first threshold SOC. In one example, method 600 may judge that the SOC is or is expected to be greater than the first threshold SOC based on the initial battery SOC immediately before charging, the rate of charge to be delivered to the traction battery, and an expected amount of time to charge the traction battery. If method 600 judges that the SOC estimate during charging will or is expected to exceed a first threshold amount of charge, the answer is yes and method 600 proceeds to 612. Otherwise, the answer is no and method 600 proceeds to 614.

At 612, method 600 selects the method of FIG. 5 and charges the vehicle's traction battery according to the method of FIG. 5. The method of FIG. 5 may provide more accurate SOC estimates when cutting off charge to the traction battery is permitted while the vehicle is electrically coupled to the EVSE and when SOC estimates are or are expected to be greater than the first threshold SOC amount. Method 600 proceeds to exit.

At 614, method 600 selects the method of FIG. 3 and charges the vehicle's traction battery according to the method of FIG. 3. The method of FIG. 3 may provide more accurate SOC estimates when cutting off charge to the traction battery is not permitted while the vehicle is electrically coupled to the EVSE and when SOC estimates are or are expected to be less than a first threshold SOC amount. Method 600 proceeds to exit.

In this way, method 600 may select a method for charging a traction battery and the selected charging method may provide greater accuracy for SOC estimates. The method considers different SOC estimation attributes and SOC level to select a SOC estimation process.

Referring now to FIG. 7, a method for charging individual cells of a traction battery and selecting a traction battery charging procedure from a plurality of traction battery charging procedures is shown. Method 700 may be performed via a controller (e.g., electric energy storage device controller 139) in cooperation with the system of FIG. 1 to control traction battery charging. At least portions of method 700 may be included in and cooperate with a system as shown in FIG. 1 as executable instructions stored in non-transitory memory. The method of FIG. 7 may cause the controller to actuate the actuators in the real world and receive data and signals from sensors described herein when the method is realized as executable instructions stored in controller memory.

At 702, method 700 determines a requested SOC. In one example, a human vehicle operator may request a SOC value to a value greater than zero and less than or equal to 100%. The human vehicle operator may input the requested SOC into a human/machine interface 140. Alternatively, a cloud server may request that the vehicle be charged to a particular SOC value via a satellite, cellular network, or means of communication. The requested SOC may be converted into a requested SOC for each battery cell of the traction battery. Thus, the requested SOC may be for an individual or sole battery cell of a traction battery. Method 700 proceeds to 704.

At 704, method 700 retrieves from controller memory (e.g., random access memory) SOC correction values from prior traction battery charging procedures. Method 700 may retrieve a predetermined actual total number of SOC correction values for consistency. The SOC correction values may be accumulated during charging of a traction battery while estimating SOC for the traction battery via a first method, a second method, or a third method. Method 700 proceeds to 706 after retrieving the SOC correction values.

At 706, method 700 begins charging the traction battery. The traction battery may begin charging after the vehicle communicates to the EVSE that charging may begin. The vehicle may communicate to the EVSE that charging may begin after information is exchanged between the vehicle having the traction battery that is about to be charged and the EVSE. Method 700 proceeds to 708.

At 708, method 700 adaptively selects a SOC estimation algorithm based on a least SOC charge correction value from prior traction battery charging events and time spent charging the traction battery during the present period when the vehicle is electrically coupled to the EVSE. Additionally, method 700 may consider the rate that charge flows to from the EVSE to the traction battery to adaptively select the SOC estimation algorithm.

In one example, method 700 may break battery charging rate into three or more groups (e.g., low rate, middle rate, and high rate of charging). Method 700 may also break amount of battery charging time into three or more groups (e.g., low charging time, middle charging time, long charging time) and each battery charging method may be assigned values according to the present traction battery charging rate and charging time. For example, for lower rates of charging the method of FIG. 4 may be assigned a lower numeric value while the methods of FIGS. 3 and 5 may be assigned a higher numeric value. For higher rates of charging, the methods of FIGS. 3 and 5 may be assigned lower numeric values and the method of FIG. 4 may be assigned a higher numeric value. Similarly, for shorter periods of time a traction battery has been charging, the method of FIG. 4 may be assigned a smaller numeric value and the methods of FIGS. 3 and 5 may be assigned larger numeric values. For longer periods of time the traction battery has been charging, the method of FIG. 4 may be assigned a larger numeric value and the methods of FIGS. 3 and 5 may be assigned smaller numeric values.

The SOC correction values for the method of FIG. 3 may be added with the numeric values for rate of charge and amount of time charging for the method of FIG. 3 to generate an accumulated value for the method of FIG. 3. Similarly, the SOC correction values for the method of FIG. 4 may be added with the numeric values for rate of charge and amount of time charging for the method of FIG. 4 to generate an accumulated value for the method of FIG. 4. Likewise, the SOC correction values for the method of FIG. 5 may be added with the numeric values for rate of charge and amount of time charging for the method of FIG. 5 to generate an accumulated value for the method of FIG. 5. Method 700 may then select whichever of the method of FIG. 3, the method of FIG. 4, and the method of FIG. 5 that has the lowest accumulated value as the basis for estimating SOC for the traction battery during the charging period. Method 700 proceeds to 710.

At 710, method 700 corrects the present SOC, which may be estimated based on Coulomb counting, according to the selected SOC algorithm. In one example, the correction may be determined via the following equation:

$$SOCcorr ( t ) = ( SOCcoul ( t ) - SOCsel ) \cdot {G}_{2}$$

where SOCcorr(t) is SOC correction at the present time t, SOCcoul is SOC based on Coulomb counting according to

$$SOCcoul ( t ) = SOCcoul ( {t}_{0} ) + {\int }_{{t}_{0}}^{t} \frac{I}{{Q}_{n}} .$$

dt, t₀ is an initial time, I is current, and Qₙ is charge capacity of the battery, SOCsel is the SOC estimate for the individual battery cell generated by applying the selected SOC determining method, and G2 is a predetermined gain value (e.g., a real number).

The present SOC is adjusted according to the correction value via the following equation to generate a corrected SOC:

$$corSOC ( t ) = SOCcoul ( t ) + SOCcorr ( t )$$

where corSOC is the corrected SOC. Method 700 proceeds to 712.

At 712, method 700 stores to memory (e.g., random access memory) the correction accumulate in step 710. Method 700 proceeds to 714.

At 714, method 700 judges whether or not the traction battery is charge to the corrected SOC. If so, the answer is yes and method 700 proceeds to 716. Otherwise, the answer is no and method 700 returns to 710.

At 716, method 700 ceases charging the traction battery. Method 700 proceeds to exit after ceasing traction battery charging.

In this way, method 700 may select a method to correct SOC according to correction values of a plurality of SOC correction methods. The SOC correction method may be selected based on charging rate of the traction battery, the most recent amount of time that the traction battery has been charging, and accumulated SOC correction values.

The methods of FIGS. 6 and 7 may provide for a method for charging a traction battery of a vehicle to a requested state of charge (SOC), comprising: retrieving from memory a predetermined number of SOC correction values accumulated during charging of the traction battery via a first SOC estimation algorithm, a second SOC estimation algorithm, or a third SOC estimation algorithm; charging the traction battery; correcting a present SOC estimate via a selected SOC estimation algorithm to generate a corrected SOC, the selected SOC estimation algorithm selected from a plurality of algorithms; and ceasing charging of the traction battery based on the corrected SOC. In a first example, the method further comprises storing in memory a present SOC correction value accumulated via applying the selected SOC estimation algorithm. In a second example that may include the first example, the method includes where the first SOC algorithm is based on a battery open circuit voltage, target control voltage, and a minimum cutoff current. In a third example that may include one or both of the first and second examples, the method includes where the second SOC algorithm is based on an instantaneous SOC estimate. In a fourth example that may include one or more of the first through third examples, the method includes where the instantaneous SOC estimate is based on an instantaneous voltage of the traction battery and an instantaneous current of the traction battery. In a fifth example that may include one or more of the first through fourth examples, the method includes where the third SOC algorithm is based on a battery open circuit voltage while the traction battery is maintained with zero input and output current. In a sixth example that may include one or more of the first through fifth examples, the method includes where the requested SOC is less than 100%. In a seventh example that may include one or more of the first through sixth examples, the method further comprises adaptively selecting the SOC estimation algorithm based on a least accumulated SOC correction and an amount of time charging the traction battery since the vehicle was most recently coupled to electric vehicle supply equipment.

The methods of FIGS. 6 and 7 also provide for a method for charging a traction battery, comprising: estimating a state of charge of the traction battery via Coulomb counting; and correcting the state of charge via an open circuit voltage based state of charge estimate for the traction battery. In a first example, the method includes where correcting the state of charge via the open circuit voltage is performed in response to the state of charge being greater than a threshold state of charge. In a second example that may include the first example, the method further comprises correcting the state of charge via an instantaneous state of charge estimate in response to the state of charge being less that the threshold state of charge. In a third example that may include one or both of the first and second examples, the method includes where the instantaneous state of charge is based on an instantaneous voltage of the traction battery, an instantaneous current of the traction battery, and an instantaneous temperature of the traction battery. In a fourth example that may include one or more of the first through third examples, the method includes where correcting the state of charge via the instantaneous state of charge is performed after charging the traction battery for a predetermined amount of time.

Note that the example control and estimation routines included herein can be used with various engine and/or vehicle system configurations. The control methods and routines disclosed herein may be stored as executable instructions in non-transitory memory and may be carried out by the control system including the controller in combination with the various sensors, actuators, and other engine hardware. The specific routines described herein may represent one or more of any number of processing strategies such as event-driven, interrupt-driven, multi-tasking, multi-threading, and the like. As such, various actions, operations, and/or functions illustrated may be performed in the sequence illustrated, in parallel, or in some cases omitted. Likewise, the order of processing is not necessarily required to achieve the features and advantages of the example embodiments described herein, but is provided for ease of illustration and description. One or more of the illustrated actions, operations and/or functions may be repeatedly performed depending on the particular strategy being used. Further, at least a portion of the described actions, operations and/or functions may graphically represent code to be programmed into non-transitory memory of the computer readable storage medium in the control system. The control actions may also transform the operating state of one or more sensors or actuators in the physical world when the described actions are carried out by executing the instructions in a system including the various engine hardware components in combination with one or more controllers.

This concludes the description. The reading of it by those skilled in the art would bring to mind many alterations and modifications without departing from the spirit and the scope of the description.

1. A method for charging a traction battery of a vehicle to a requested state of charge (SOC), comprising:
retrieving from memory a predetermined number of SOC correction values accumulated during charging of the traction battery via a first SOC estimation algorithm, a second SOC estimation algorithm, or a third SOC estimation algorithm;
charging the traction battery;
correcting a present SOC estimate via a selected SOC estimation algorithm to generate a corrected SOC, the selected SOC estimation algorithm selected from a plurality of algorithms; and
ceasing charging of the traction battery based on the corrected SOC.

2. The method of claim 1, further comprising storing in memory a present SOC correction value accumulated via applying the selected SOC estimation algorithm.

3. The method of claim 1, where the first SOC estimation algorithm is based on a battery open circuit voltage, a target control voltage, and a minimum cutoff current.

4. The method of claim 1, where the second SOC estimation algorithm is based on an instantaneous SOC estimate.

5. The method of claim 4, where the instantaneous SOC estimate is based on an instantaneous voltage of the traction battery and an instantaneous current of the traction battery.

6. The method of claim 1, where the third SOC estimation algorithm is based on a battery open circuit voltage while the traction battery is maintained with zero input and output current.

7. The method of claim 1, where the requested SOC is less than 100%.

8. The method of claim 1, further comprising adaptively selecting the selected SOC estimation algorithm based on a least accumulated SOC correction and an amount of time charging the traction battery since the vehicle was most recently coupled to electric vehicle supply equipment.

9. A system, comprising:
a traction battery; and
a controller including executable instructions that cause the controller to correct a Coulomb based battery state of charge value in response to a battery voltage, a battery current, and a battery temperature based battery state of charge estimate.

10. The system of claim 9, further comprising additional executable instructions that cause the controller to look up a correction value for the traction battery based on the battery voltage, the battery current, and the temperature based battery state of charge estimate.

11. The system of claim 9, further comprising additional executable instructions to supply charge to the traction battery for a predetermined amount of time.

12. The system of claim 11, further comprising additional executable instructions to supply charge to the traction battery via less than a threshold amount of current.

13. The system of claim 12, further comprising additional executable instructions to report when the battery state of charge is equal to a requested battery state of charge.

14. The system of claim 13, where the requested battery state of charge is received via a human/machine interface.

15. The system of claim 14, further comprising additional executable instructions to reset an amount of time that the traction battery has been charging to zero.

16. A method for charging a traction battery, comprising:
estimating a state of charge of the traction battery via Coulomb counting; and
correcting the state of charge via an open circuit voltage based state of charge estimate for the traction battery.

17. The method of claim 16, where correcting the state of charge via the open circuit voltage is performed in response to the state of charge being greater than a threshold state of charge.

18. The method of claim 17, further comprising correcting the state of charge via an instantaneous state of charge estimate in response to the state of charge being less that the threshold state of charge.

19. The method of claim 18, where the instantaneous state of charge is based on an instantaneous voltage of the traction battery, an instantaneous current of the traction battery, and an instantaneous temperature of the traction battery.

20. The method of claim 19, where correcting the state of charge via the instantaneous state of charge is performed after charging the traction battery for a predetermined amount of time.
